(19) United States
(12) Patent Application Publication
(10) Pub. No.: US 2007/0001182 A1
(43) Pub. Date: Jan. 4, 2007

(54) Structured phosphor tape article

(75) Inventors: Craig R. Schardt, St. Paul, MN (US); David Scott Thompson, Woodbury, MN (US); Larry A. Meixner, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/171,933

(22) Filed: Jun. 30, 2005

(51) Int. Cl. H01L 33/00; H01J 63/04

(52) U.S. Cl. 257/98; 257/99; 257/100; 313/503; 313/504

(57) ABSTRACT

A phosphor tape article includes a phosphor layer having a phosphor and a polymeric binder material and a structured surface, and a pressure sensitive adhesive layer disposed adjacent the phosphor layer such that light transmitted through the pressure sensitive layer is received by the phosphor layer through the structured surface. The pressure sensitive layer can also have one or more structured surface, which in some cases can be complimentary with the structured surface of the phosphor layer. Light emitting devices including phosphor tape and methods of making such devices are also disclosed.

### BACKGROUND

The present application relates to structured phosphor tape articles and specifically to phosphor tape articles that include a pressure sensitive adhesive layer and a structured phosphor layer.

Many white light sources that utilize LEDs in their construction can have two basic configurations. In one, referred to herein as direct emissive LEDs, white light is generated by direct emission of different colored LEDs. Examples include a combination of a red LED, a green LED, and a blue LED, and a combination of a blue LED and a yellow LED. In another basic configuration, referred to herein as LED-excited phosphor LEDs, a single LED generates a beam in a narrow range of wavelengths, which beam impinges upon and excites a phosphor material to produce visible light. The phosphor can comprise a mixture or combination of distinct phosphor materials, and the light emitted by the phosphor can include a plurality of narrow emission lines distributed over the visible wavelength range such that the emitted light appears substantially white to the unaided human eye.

One method for producing white (broad-spectrum) light from LEDs is to combine a blue or ultraviolet (UV) emitting LED with a suitable phosphor or blend of phosphors. In practice, phosphor powder is either coated directly onto the LED die or dispersed in the polymer encapsulant surrounding the LED die. One example of a white light LED is formed by combining a blue light emitting InGaN LED encapsulated with a yellow emitting phosphor such as cerium-doped yttrium aluminum garnet (YAG:Ce). White light is produced by this combination when the right amount of phosphor is deposited over the blue die to absorb most, but not all, of the blue light such that unabsorbed blue light and yellow light combine to create light that appears white.

Producing packaged white LEDs having a consistent white color requires careful control of the quality of phosphor deposited over the LED. Too little phosphor causes the LED emission to appear blue white while too much phosphor causes the emission to appear yellow. Accurately controlling the amount of phosphor deposited is difficult as package size (volume) decreases. The encapsulant dispensing system must have a dispensing precision on the order or tens of nanoliters and high phosphor loadings are difficult to dispense due to the non-Newtonian flow behavior of the phosphor loaded resins and clogging of the dispenser from phosphor agglomerates.

Incorporating the phosphor in the encapsulant also presents problems with manufacturing yield and quality control. Due to variation in semiconductor manufacturing and variation in the quality of encapsulant deposited in the LED package, each white LED must be tested and measured after encapsulation to determine its individual color and brightness. Based on this testing, the white light LEDs are sorted into bins. White LEDs that are too far out of tolerance cannot be reworked and are scrapped. Bubbles trapped in the encapsulant and inhomogeneous distribution of phosphor are other problems that are inherent in current white LED production and lead to additional yield loss.

### BRIEF SUMMARY

Phosphor tape articles are disclosed herein that include a pressure sensitive adhesive layer and a structured phosphor layer. These phosphor tape articles can be adhered to encapsulated LEDs to produce light emitting devices that possess greater color consistency and/or predictability.

With regard to the phosphor tape article itself, such an article can include a phosphor layer having a phosphor and a polymeric binder material, where the phosphor layer has a structured surface, and a pressure sensitive adhesive layer disposed adjacent the phosphor layer such that light transmitted through the pressure sensitive adhesive layer is received by the phosphor layer through the structured surface. The pressure sensitive adhesive layer can also have one or more structured surfaces. In some cases the pressure sensitive adhesive layer has on a side thereof facing the phosphor layer a structured surface that is complimentary with the structured surface of the phosphor layer. In some cases the pressure sensitive adhesive layer has on a side opposite the phosphor layer a structured surface that forms pathways allowing egress of fluids as the phosphor tape is being applied to an LED encapsulant or another suitable substrate.

With regard to light emitting devices that may incorporate a phosphor tape, such devices can include an encapsulated ultraviolet or blue LED die and a phosphor tape disposed thereon. The phosphor tape includes a phosphor layer having a phosphor and a polymeric binder material and a pressure sensitive adhesive layer disposed on the phosphor layer. The phosphor layer has on a side thereof facing the pressure sensitive adhesive layer a structured surface. The pressure sensitive adhesive layer can have on a side thereof facing the phosphor layer a structured surface that is complimentary with the structured surface of the phosphor layer.

These and other aspects of this application will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

The disclosure may be more completely understood in consideration of the following detailed description of various embodiments in connection with the accompanying drawings, where like reference numerals designate like elements, and where:

FIG. 1 is a schematic cross-sectional view of an illustrative phosphor tape article;

FIG. 1a is a schematic cross-sectional view of another illustrative phosphor tape article;

FIG. 2 is a schematic cross-sectional view of another illustrative phosphor tape article;

FIG. 3 is a schematic perspective view of an illustrative phosphor tape article;

FIG. 4 is a schematic perspective view of another illustrative phosphor tape article;

FIG. 5 is a schematic cross-sectional view of an illustrative piece of phosphor tape being applied to an encapsulated LED;

FIG. 6 is a schematic cross-sectional view of an illustrative light emitting device;

FIG. 7 is a schematic cross-sectional view of another illustrative light emitting device; and

FIG. 8 is a perspective view of a sheet of phosphor tape.

### DETAILED DESCRIPTION OF ILLUSTRATIVE EMBODIMENTS

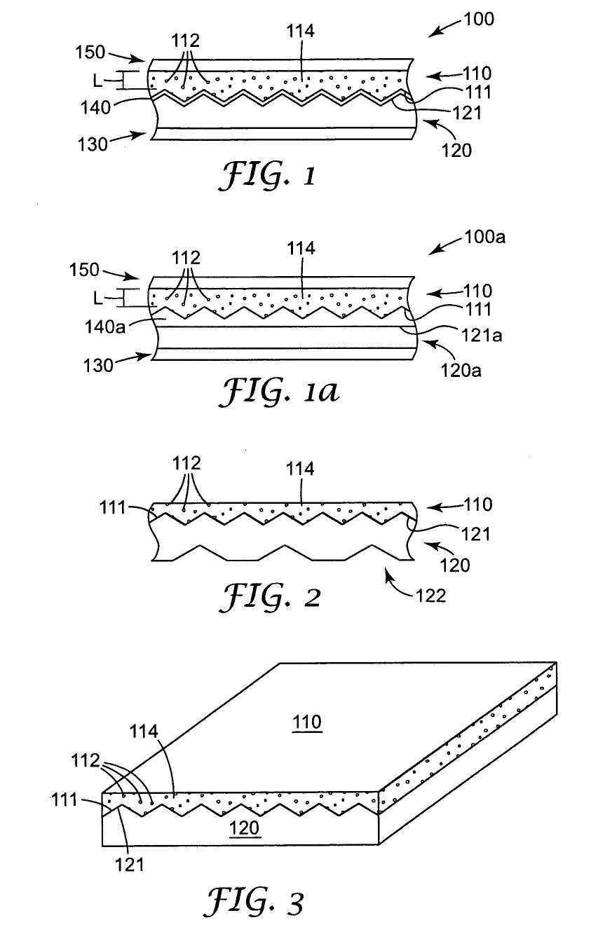

FIG. 1 is a schematic cross-sectional view of an illustrative phosphor tape article 100. The phosphor tape article 100 includes a phosphor layer 110 disposed adjacent a pressure sensitive adhesive layer 120 such that light transmitted through the pressure sensitive adhesive layer 120 is received by the phosphor layer 110. In this regard, “adjacent” denotes a relative positioning of two articles that are near one another; adjacent items can be touching, or separated by one or more layers. The phosphor layer 110 includes a structured surface 111. The adhesive layer 120 includes a structured surface 121 that is complimentary with the phosphor layer structured surface 111. The term “complimentary” refers to an article surface that generally interlocks, mates or aligns with a second article surface, this term includes perfect matching and imperfect matching.

The phosphor tape article 100 can optionally include one or more substrate layers 140 disposed between the phosphor layer 110 and the pressure sensitive adhesive layer 120. In many embodiments, the substrate layer 140 is complimentary with both the adhesive layer 120 structured surface 121 (if present) as well as with the phosphor layer 110 structured surface 111. An optional release liner layer 130 can be disposed on the pressure sensitive adhesive layer 120 on a side opposite the phosphor layer. An outer protective layer or hardcoat layer 150 can also be disposed atop or adjacent the phosphor layer 110.

The phosphor layer 110 includes a phosphor 112 and a polymeric binder material 114. “Polymeric” or “polymer” will be understood to include polymers, copolymers, oligomers and combinations thereof, as well as polymers, oligomers, or copolymers that can be formed in a miscible blend. The phosphor 112 is preferably highly efficient and suitable for use with LED devices, the phosphor desirably having a decay rate of less than five seconds, alternatively less than 1, 0.1, 0.01, or 0.001 second. The decay rate in this regard refers to the characteristic time τ it takes for the phosphor emission to decay to 1/e (about 37%) of its initial intensity after the excitation light is turned off. The polymeric binder 114 can be any useful material such as, for example, fluoropolymers, polyacrylates, epoxies, silicones, polycarbonates, and polyimides. In many embodiments, the polymeric binder 114 has a low absorption for the excitation light (supplied, for example, by an LED) and a low absorption for the phosphor 112 emission.

The thickness between the bottom of the structured surface 111 and the opposing surface of the phosphor layer 110 defines a land L. In some embodiments, the land L has a thickness value from 0 to 50% or from 0 to 25% or from 0 to 10% of the total thickness of the phosphor layer 110. Thus, where the thickness of the land L is 0%, the phosphor layer 110 contains substantially no land L at all.

Illustrative embodiments disclosed herein are operative with a variety of phosphor materials or blends of phosphor 112 materials. In many embodiments, the phosphor materials are inorganic in composition, having excitation wavelengths in the 300-475 nanometer range and emission wavelengths in the visible wavelength range. In this regard, visible light refers to light that is perceptible to the unaided human eye, generally in the wavelength range from about 400 to 700 nm. In the case of phosphor materials having a narrow emission wavelength range, a mixture of phosphor materials can be formulated to achieve the desired color balance, as perceived by the viewer, for example a mixture of red-, green- and blue-emitting phosphors. Phosphor materials having broader emission bands are useful for phosphor mixtures having higher color rendering indices. Phosphors that convert light in the range of about 300 to 475 nm to longer wavelengths are known. See, for example, the line of phosphors offered by Phosphor Technology Ltd., Essex, England. Phosphors include rare-earth doped garnets, silicates, and other ceramics. In some embodiments, the phosphor is selected to provide a light source emission of one color such as for example, green or red. In other embodiments, the phosphor is selected to provide a light source that emits white light. “White light” here refers to light that stimulates the red, green, and blue sensors in the human eye to yield an appearance that an ordinary observer would consider white. Such light may be biased to the red (commonly referred to as warm white light) or to the blue (commonly referred to as cool white light), and can have a color rendering index of up to 100.

The phosphor (fluorescent material) 112 can be or comprise inorganic particles, organic particles, or organic molecules or a combination thereof. Useful inorganic particles include doped garnets (such as YAG:Ce and (Y,Ga)AG:Ce), aluminates (such as Sr₂Al₁₄O₂₅:Eu and BAM:Eu), silicates (such as europium doped strontium barium silicate), sulfides (such as ZnS:Ag, CaS:Eu, and SrGa₂S₄:Eu), oxy-sulfides, oxy-nitrides, phosphates, borates, and tungstates (such as CaWO₄). These materials may be in the form of conventional phosphor powders or nanoparticle phosphor powders. Another class of useful inorganic particles are quantum dot phosphors made of semiconductor nanoparticles including Si, Ge, CdS, CdTe, ZnS, ZnSe, ZnTe, PbS, PbSe, PbTe, InN, InAs, AlN, AlP, AlAs, GaN, GaP, GaAs and combinations thereof. The surface of the quantum dot can be at least partially coated with an organic molecule to prevent agglomeration and increase compatibility with the binder. In some cases the semiconductor quantum dot may be made up of several layers of different materials in a core-shell construction.

In many embodiments, the phosphor exhibits durable and stable optical properties. The phosphor layer can consist of a blend of different types of phosphors in a single layer or a series of layers, each containing one or more types of phosphors. The inorganic phosphor particles in the phosphor layer may vary in size (diameter) and they may be segregated such that the average particle size is not uniform across the cross-section of the phosphor layer. In some embodiments, the phosphor particles have a size in the 1 to 25 micrometer range.

The phosphor layer 110 can have any useful thickness. In many embodiments, the phosphor layer 110 has a thickness in a range from 10 to 500 micrometers, or from 10 to 250 micrometers, or from 25 to 150 micrometers. The phosphor layer 110 can be coated out to form a layer having a substantially uniform phosphor coating weight along the layer. In some cases, the phosphor coating weight can be uniform to within 0% to 5%, 0% to 4%, 0% to 3%, 0% to 2%, or 0% to 1% of a nominal or average value along the phosphor layer 110 length and/or width. The nominal value of the phosphor coating weight can be selected depending on the layer thickness and desired output color. Where the phosphor tape article 100 is made on a conventional film line, the width of phosphor layer 100 may be a meter or more, and the length may be many tens or hundreds of meters or more.

The phosphor layer 110 can be substantially light scattering. In many embodiments, the phosphor layer 110 has a haze value in a range from 50 to 100%, or from 75 to 100%, or from 90 to 100%, or from 95 to 100%, or from 99 to 100%. The phosphor layer 110 haze value can be measured by accepted test methods and instruments, including standard test method ASTM D1003-95.

The structured surface 111 can include any useful projections or depressions that aid in decreasing the reflection of light at the phosphor layer 110. In some embodiments, the structures are a plurality of parallel longitudinal ridges extending along a length or width of the phosphor layer 110. These ridges can be formed from a plurality of prism apexes. These apexes can be sharp, rounded or flattened or truncated, as desired. These include regular or irregular prismatic patterns which can be an annular prismatic pattern, a cube-corner pattern or any other lenticular microstructure. In some embodiments, the structures include a plurality of pyramidal or conical projections or depressions that are discrete or linear projections or depressions along a side of the phosphor layer. In many embodiments, the structures have an aspect ratio (height/width) in a range from 0.5 to 20, from 0.5 to 10, or from 1 to 10.

The complimentary structured surfaces 111 and 121 may be fabricated by any suitable contacting technique, such as casting, coating, or compressing. The structured surfaces 111 and 121 may be made by at least one of: (1) casting the PSA layer 120 and/or phosphor layer 110 on a tool with an embossed pattern, (2) coating the PSA layer onto a release liner with an embossed pattern, or (3) passing the PSA layer 120 and/or phosphor layer 110 through a nip roll to compress the PSA layer 120 and/or phosphor layer 110 against a release liner with an embossed pattern. The topography of the tool used to create the embossed pattern may be made using any known technique, such as, for example, chemical etching, mechanical etching, laser ablation, photolithography, stereolithography, micromachining, knurling, cutting, or scoring. In addition, the complimentary surfaces can be formed by coating one layer onto the other structured layer. For example, the phosphor layer 110 can be structured as described above and then the PSA layer 120 can be coated onto the phosphor layer 110 structured surface 111 to form the complimentary PSA surface 121 (see, e.g., FIG. 2 or FIG. 3).

The pressure sensitive adhesive layer 120 can be formed from a variety of polymeric materials. The Pressure-Sensitive Tape Council (Test Methods for Pressure Sensitive Adhesive Tapes (1994), Pressure Sensitive Tape Council, Chicago, Ill.) has described pressure sensitive adhesives (PSAs) as material with the following properties: (1) aggressive and permanent tack, (2) adherence with no more than finger pressure, (3) sufficient ability to hold onto an adherand, (4) sufficient cohesive strength, and (5) requires no activation by an energy source. PSAs are normally tacky at assembly temperatures, which is generally room temperature or greater (i.e., about 20° C. to about 30° C. or greater). In many embodiments, the PSA has a low absorption for the LED emission and the phosphor emission. The PSA chemistry can be selected to bond strongly with an LED encapsulant material. Exemplary PSAs exhibit a low initial bond strength to allow for reworking and build adhesion over time to a strong bond. In some embodiments, the PSA can cure or cross-link (via heat or light) to create a permanent or structural bond. The PSA layer 120 can be any useful thickness such as, for example, 10 to 250 micrometers, or 10 to 150 micrometers, as desired. In some embodiments, the PSA layer 120 is patterned (as shown in FIG. 2 and described above) on a side opposite the phosphor layer to facilitate the removal of air from an interface between the PSA and the adhered substrate during application.

Materials that function well as PSAs are polymers designed and formulated to exhibit the requisite viscoelastic properties resulting in a desired balance of tack, peel adhesion, and shear holding power at the assembly temperature. Polymers used for preparing PSAs are natural rubber-, synthetic rubber- (e.g., styrene/butadiene copolymers (SBR) and styrene/isoprene/styrene (SIS) block copolymers), silicone elastomer-, poly alpha-olefin-, and various (meth) acrylate- (e.g., acrylate and methacrylate) based polymers. Of these, (meth)acrylate-based polymer PSAs are an example of a class of PSA due to their optical clarity, permanence of properties over time (aging stability), and versatility of adhesion levels, to name just a few benefits. It is known to prepare PSAs comprising mixtures of certain (meth)acrylate-based polymers with certain other types of polymers (Handbook of Pressure Sensitive Adhesive Technology, 2nd Edition, Edited by D. Satas, page 396, 1989). In some embodiments, the PSA is formed from a silicone material. In some embodiments, the PSA layer includes a curing or cross-linking agent. In further embodiments, the PSA layer can include a tackifying agent.

Particularly suitable PSAs exhibiting good environmental stability are described in the following three references: (1) published U.S. application US 2004/0202879 (Xia et al.); (2) U.S. application Ser. No. 10/901,629 entitled “(Meth)acrylate Block Copolymer Pressure Sensitive Adhesives” and filed Jul. 29, 2004; and (3) U.S. application Ser. No. 11/015,406 entitled “Optically Clear Pressure Sensitive Adhesive” and filed Dec. 17, 2004. Each of these references is incorporated herein by reference in its entirety. The first reference describes, among other things, adhesive compositions comprising a blend of: a majority of a pressure sensitive adhesive component comprising at least one polymer with an acid or base functionality; a high Tg polymer with an weight average molecular weight greater than 100,000 comprising an acid or base functionality; and a crosslinker; wherein the functionality of the pressure sensitive adhesive component and the functionality of the high Tg polymer form an acid-base interaction when mixed. The second reference describes, among other things, optically clear pressure sensitive adhesive layers comprising a (meth)acrylate block copolymer including: (i) at least two A block polymeric units that are the reaction product of a first monomer composition comprising an alkyl methacrylate, an aralkyl methacrylate, an aryl methacrylate, or a combination thereof, each A block having a Tg of at least 50° C., the (meth)acrylate block copolymer comprising 20 to 50 weight percent A block; and (ii) at least one B block polymeric unit that is the reaction product of a second monomer composition comprising an alkyl (meth)acrylate, a heteroalkyl (meth)acrylate, a vinyl ester, or a combination thereof, the B block having a Tg no greater than 20° C., the (meth)acrylate block copolymer comprising 50 to 80 weight percent B block. The third reference describes, among other things, optically clear pressure sensitive adhesive films that include: a pressure sensitive adhesive formed by polymerizing a (C₁-C₈)alkyl (meth)acrylate monomer; and a plurality of surface modified nanoparticles dispersed in the pressure sensitive adhesive.

Curing or cross-linking agents can increase cohesive strength of the PSA. Two main types of curing or crosslinking additives are commonly used. The first crosslinking additive is a thermal crosslinking additive such as a multifunctional aziridine. One example is 1,1′-(1,3-phenylene dicarbonyl)-bis-(2-methylaziridine) (CAS No. 76522-64-4), referred to herein as “Bisamide”. Such chemical crosslinkers can be added into solvent-based PSAs after polymerization and activated by heat during oven drying of the coated adhesive. In some cases, chemical crosslinkers that rely upon free radicals to carry out the crosslinking reaction may be employed. Reagents such as, for example, peroxides serve as a source of free radicals. When heated sufficiently, these precursors will generate free radicals which bring about a crosslinking reaction of the polymer. One example of a free radical generating reagent is benzoyl peroxide. If present, free radical generators are usually required only in small quantities, but generally require higher temperatures to complete a crosslinking reaction than those required for the bisamide reagent. A second type of chemical crosslinker or curing agent is a photosensitive crosslinker or a photo-curing agent which is activated by high intensity light (such as ultraviolet and/or blue light.) Two useful photosensitive crosslinkers are benzophenone and/or a triazine, for example, 2,4-bis(trichloromethyl)-6-(4-methoxy-phenyl)-s-triazine. These crosslinkers are activated by UV light generated from artificial sources such as medium pressure mercury lamps or a UV blacklight. “UV” or “ultraviolet” refers to light whose wavelength is in the range from about 300 to about 400 nm. Hydrolyzable, free-radically copolymerizable crosslinkers, such as monoethylenically unsaturated mono-, di-, and trialkoxy silane compounds including, but not limited to, methacryloxypropyltrimethoxysilane (available from Gelest, Inc., Tullytown, Pa.), vinyldimethylethoxysilane, vinylmethyldiethoxysilane, vinyltriethoxysilane, vinyltrimethoxysilane, vinyltriphenoxysilane, and the like, are also useful crosslinking agents. Crosslinking may also be achieved using high energy electromagnetic radiation such as gamma or e-beam radiation. In some embodiments crosslinker is not present in the PSA layer.

Tackifiers and/or plasticizers may be added to aid in optimizing the ultimate modulus, Tg, tack and peel properties of the PSA. Examples of useful tackifiers include, but are not limited to, rosin, rosin derivatives, polyterpene resins, coumarone-indene resins, and the like. Plasticizers which may be added to the adhesive may be selected from a wide variety of commercially available materials. In each case, the added plasticizer can be compatible with the PSA. Representative plasticizers include polyoxyethylene aryl ether, dialkyl adipate, 2-ethylhexyl diphenyl phosphate, t-butylphenyl diphenyl phosphate, (2-ethylhexyl) adipate, toluenesulfonamide, dipropylene glycol dibenzoate, polyethylene glycol dibenzoate, polyoxypropylene aryl ether, dibutoxyethoxyethyl formal, and dibutoxyethoxyethyl adipate.

When present, the substrate layer 140 can be formed from a polymeric material such as, for example a polyolefin, a polyester, and/or a polyacrylate. The substrate layer 140 can have any useful thickness such as, for example, from 10 to 1000 micrometers, or from 10 to 500 micrometers, or from 10 to 100 micrometers. In some embodiments the substrate layer 140 provides a base or web of material on which to coat the phosphor layer 110 and/or the PSAlayer 120. In other embodiments, the phosphor layer 110 is coated directly onto the prPSAlayer 120. In further embodiments, the PSA layer 120 is coated directly onto the phosphor layer 110.

An optional polymeric release layer 130 protects the properties of the pressure sensitive adhesive layer 120 so that the article 100 can be manipulated and subsequently separated from the release layer 130 to expose the PSA layer 120. These release polymers rely on low surface energy to deliver the release property. A partial listing of low surface energy functional groups on polymers includes silicones, fluorocarbons, and long chain, crystalline hydrocarbons. The release liner layer 130 can have any useful thickness such as, for example from 10 to 100 micrometers.

In some embodiments, a protective or hardcoat layer 150 can be disposed on the phosphor layer 110. This hardcoat layer 150 may contain inorganic oxide particles, e.g., silica, of nanometer dimensions dispersed in a binder precursor resin matrix. The optional hardcoat can have any useful thickness such as, for example, in a range of 1 to 15 micrometers.

FIG. 1a depicts an illustrative phosphor tape article 100a which is similar to article 100, except that substrate layer 140 has been replaced with a thicker substrate layer 140a, which layer 140a has an upper surface that is complimentary with structured surface 111 and a lower surface that is not complementary with surface 111. Further, pressure sensitive adhesive layer 120 has been replaced with pressure sensitive adhesive layer 120a, which layer 120a has no surface that is complementary with structured surface 111. The upper (structured) surface 121 of layer 120 has been replaced by a substantially flat surface 121a of layer 120a. Layer 120a may also be modified such that only its lower surface is structured, for example so as to promote wet-out and allow egress of entrapped air during application as discussed in connection with FIG. 2.

FIG. 2 is a schematic cross-sectional view of another illustrative phosphor tape article. In this embodiment, a PSA layer 120 is disposed directly onto phosphor layer 110. The PSA layer 120 and the phosphor layer 110 are described above, except that in the embodiment of FIG. 2 the PSA layer has a structured surface 122 on a side opposite the phosphor layer 110.

The structured surface 122 can have specific shapes or microstructures that allow egress of air or other fluids trapped at the interface between the PSA 120 and a substrate during a lamination process. The microstructures of structured surface 122 can allow the PSA layer 120 to be uniformly laminated to a substrate without forming bubbles that could cause imperfections in the resulting laminate. These microstructures (and corresponding microstructures on a mating release liner) can be microscopic in at least two dimensions. The term microscopic as used herein refers to dimensions that are difficult to resolve by the human eye without the aid of a microscope. The microstructures of structured surface 122 in the PSA layer 120 may be made as described in U.S. Pat. No. 6,197,397 (Sher et al.) and U.S. Pat. No. 6,123,890 (Mazurek et al.), which are each incorporated herein by reference. The topography may be created in the PSA layer 120 by any contacting technique, such as casting, coating or compressing. The topography may be made by at least one of: (1) casting the PSA layer on a tool with an embossed pattern, (2) coating the PSA layer onto a release liner with an embossed pattern, or (3) passing the PSA layer through a nip roll to compress the PSA layer against a release liner with an embossed pattern. The topography of the tool used to create the embossed pattern may be made using any known technique, such as, for example, chemical etching, mechanical etching, laser ablation, photolithography, stereolithography, micromachining, knurling, cutting or scoring. The microstructures 122 may form a regular or a random array or pattern. Regular arrays or patterns include, for example, rectilinear patterns, polar patterns, cross-hatch patterns, cube-corner patterns. The patterns may be aligned with the direction of the carrier web, or may be aligned at an angle with respect to the carrier web. The pattern of microstructures of the PSA structured surface can define substantially continuous open pathways or grooves that extend into the PSA layer 120 from an exposed surface. The pathways either terminate at a peripheral portion of the PSA layer 120 or communicate with other pathways that terminate at a peripheral portion of the article. When the article is applied to a substrate, the pathways allow egress of fluids (such as air) trapped at an interface between the PSA layer 120 and a substrate. Preferably, the structured surface 122 disappears as the PSA layer 120 conforms to the shape of the substrate to which it is applied, e.g., an encapsulant. The shapes of the microstructures may vary widely depending on the level of fluid egress and peel adhesion required for a particular application, as well as the surface properties of the substrate. Protrusions and depressions may be used, and the microstructures may be continuous to form grooves in the PSA layer 120. Suitable shapes include hemispheres, right pyramids, trigonal pyramids, square pyramids, quadrangle pyramids, and “V” grooves, for reasons of pattern density, adhesive performance, and readily available methodology for producing the microstructures. The microstructures may be systematically or randomly generated.

The phosphor tape described above represents a significant improvement over the current practice for producing white light emitting phosphor-based LEDs. By using the phosphor tape, white light LEDs can be assembled with ease and can be produced using manual or automated assembly lines. The uniform properties of the phosphor tape provide greater color consistency and may reduce or eliminate the need for inspection and sorting of the resultant white LEDs. In many embodiments, the phosphor tape is at least temporarily re-positionable and may be removed after application in the event that an assembled device does not meet the desired specifications. In addition, a manufacturer with a supply of phosphor tapes of varying phosphor composition and thickness will have the ability to maintain a minimal inventory and produce white LEDs on-demand from standard blue or UV LEDs. A structured interface between the phosphor layer and PSA layer can improve the optical properties of the construction. For example, a phosphor layer having a structured surface facing the light source can trap more light emitted from the die and reflect less light, thus improving the efficiency of the LED device.

FIG. 3 is a schematic perspective view of an illustrative phosphor tape article. In this embodiment, the phosphor layer 110 and the PSA layer 120 have complimentary linear prismatic surfaces 111 and 121 respectively.

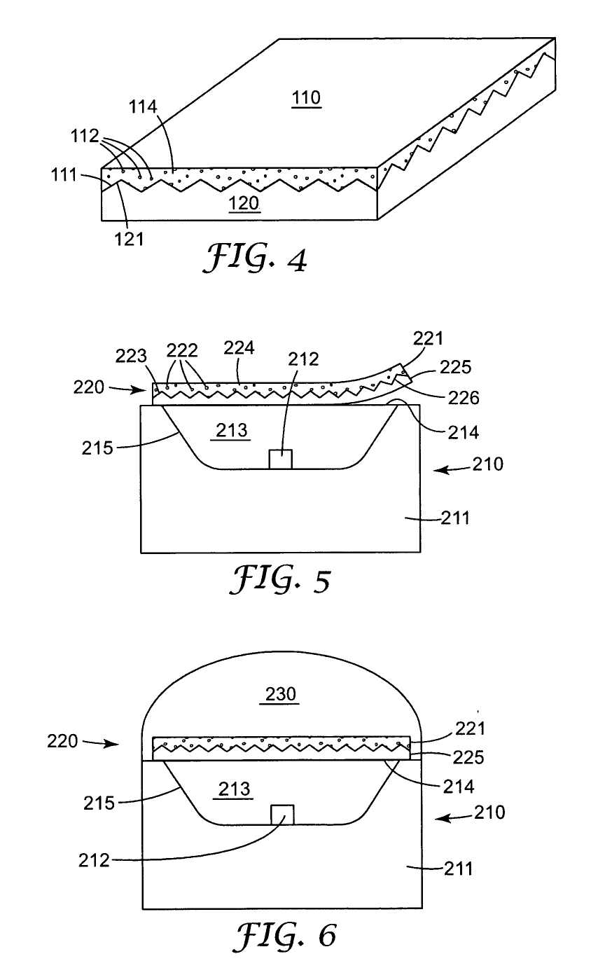

FIG. 4 is a schematic perspective view of another illustrative phosphor tape article. In this embodiment, the phosphor layer 110 and the PSA layer 120 have complimentary discrete pyramidal surfaces 111 and 121 respectively. In other embodiments the PSA layer 120 can be structured with discrete conical projections that extend into corresponding depressions in the phosphor layer 110.

FIG. 5 is a schematic cross-sectional view of an illustrative phosphor tape article 220, such as any described herein, being applied to an encapsulated LED 210 to form a light emitting device 200.

“LED” in this regard refers to a diode that emits light, whether visible, ultraviolet, or infrared. It includes incoherent encased or encapsulated semiconductor devices marketed as “LEDs”, whether of the conventional or super radiant variety. An “LED die” is an LED in its most basic form, i.e., in the form of an individual component or chip made by semiconductor processing procedures. The component or chip can include electrical contacts suitable for application of power to energize the device. The individual layers and other functional elements of the component or chip are typically formed on the wafer scale, the finished wafer can then be diced into individual piece parts to yield a multiplicity of LED dies.

The encapsulated LED 210 includes an ultraviolet or blue light emitting LED die 212 disposed within an encapsulating material 213. The LED die 212 may be the only LED die or may be one of a plurality of LED dies disposed within the encapsulated LED 210. The LED die 212 is shown disposed on a surface 215 of the LED package 211, the surface 215 defining a local aperture for light emitted by the LED die 212. In many embodiments, surface 215 is reflective. The encapsulating material 213 has an outer surface 214. The encapsulating material 213 can have any useful refractive index.

A piece of phosphor tape 220 is disposed adjacent to or on the transparent encapsulating material outer surface 214. The phosphor tape 220 can be sized to at least cover the transparent encapsulating material outer surface 214. The phosphor tape 220 can be laminated onto the transparent encapsulating material outer surface 214, as illustrated in FIG. 3. Outer surface 214 may have a variety of surface configurations. In particular, outer surface 214 can be flat or curved (whether concave or convex), or, for example, can have distinct top and side surfaces to which the piece of phosphor tape 220 is applied.

The phosphor tape 220 includes a phosphor layer 221 having a phosphor layer refractive index (typically equal to a binder material 224 refractive index) and a PSA layer 225 having a PSA layer refractive index. In many embodiments, the encapsulating material refractive index and the PSA layer refractive index are both within a value of 0.1 of each other. In another embodiment, the PSA layer refractive index and the phosphor layer refractive index are both within a value of 0.1 of each other. In a further embodiment, the encapsulating material refractive index and the PSA layer refractive index and the phosphor layer refractive index are all within a value of 0.1 of each other. In a further embodiment, the PSA layer refractive index is intermediate of the encapsulating material refractive index and the phosphor layer refractive index.

The LED excitation light can illuminate the underside of a phosphor tape article 220, which absorbs at least a portion of the excitation light and emits light at multiple wavelengths in the visible region to provide a source appearing substantially white to the ordinary observer. LED excitation light can be any light that an LED source can emit. LED excitation light can be UV, or blue light. Blue light also includes violet and indigo light.

FIG. 6 is a schematic cross-sectional view of an illustrative light emitting device similar to that of FIG. 5, except that another encapsulating layer 230 has been formed over the phosphor tape 220. The encapsulating layer 230 can be formed of the same or different material forming the encapsulating material 213 within the housing 211.

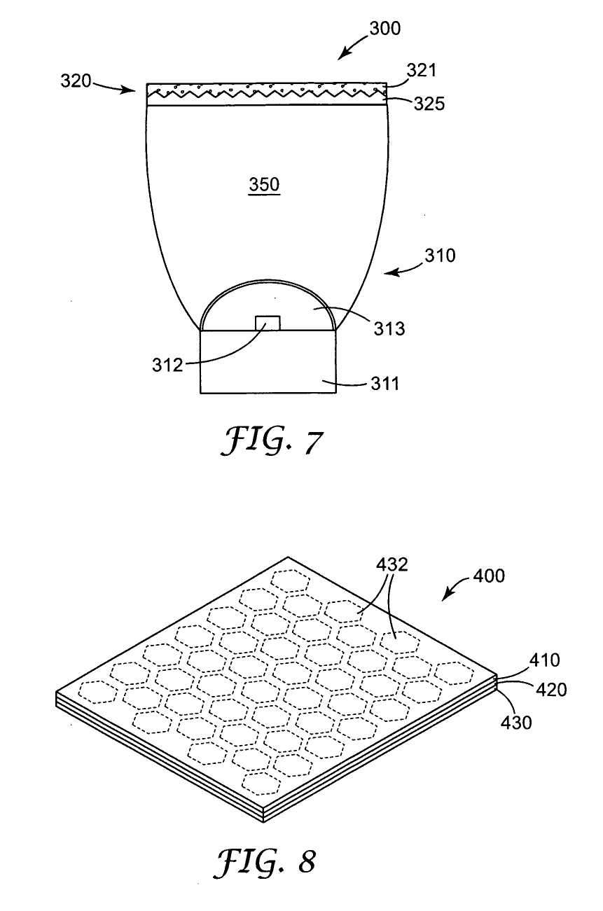

Light emitting devices can also include one or more layers or optical elements or components disposed between the encapsulated LED and the phosphor tape. Such a device is shown in schematic cross-sectional view in FIG. 7. There, light emitting device 300 includes a collimating optic disposed between an encapsulated LED die 312 and a phosphor tape 320. The phosphor tape 320 includes a pressure sensitive adhesive layer 325 (as described above) disposed between a phosphor layer 321 (as described above) and an LED 310. The LED 310 includes an optical element 350 such as, for example, a collimating optic. One or more optical elements 350 disposed between the encapsulated LED die 312 and the phosphor tape 320 can be considered to be part of a compound encapsulating body which also includes the encapsulating material 313. Thus, the phosphor tape 320 is disposed on the encapsulating material 313 and 350.

FIG. 8 is a perspective view of a sheet of phosphor tape 400. The sheet of phosphor tape 400 includes a substantially uniform phosphor layer 410 disposed adjacent to or on a PSA layer 420 and an optional release layer 430 disposed on the PSA layer 420. The phosphor tape sheet 400 may also include a carrier or substrate film (not shown). The phosphor tape sheet can be subdivided by any means such as, for example, kiss-cutting by mechanical means such as a knife, precision die cutting, or by scanning laser radiation as described in U.S. 2003/0217806 (Tait et al.). The kiss-cut lines define discrete pieces 432 of the sheet material 400, but exclusive of the carrier film (if present) which remains intact. The pieces 432 be of arbitrarily small size and shape sufficient to be disposed on individual or multiple LEDs.

Unless otherwise indicated, all numbers expressing quantities of elements, optical characteristic properties, and so forth used in the specification and claims are to be understood as being modified in all instances by the term “about.” Accordingly, unless indicated to the contrary, the numerical parameters set forth in the specification and attached claims are approximations that can vary depending upon the desired properties sought to be obtained by those skilled in the art utilizing the teachings of the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviations found in their respective testing measurements.

Weight percent, percent by weight, % by weight, and the like are synonyms that refer to the concentration of a substance as the weight of that substance divided by the weight of the composition and multiplied by 100.

The recitation of numerical ranges by endpoints includes all numbers subsumed within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. Thus, for example, reference to a composition containing “a phosphor” includes a mixture of two or more phosphors. As used in this specification and the appended claims, the term “or” is generally employed in its sense including “and/or” unless the content clearly dictates otherwise.

The present invention should not be considered limited to the particular examples described herein, but rather should be understood to cover all aspects of the invention as fairly set out in the attached claims. Various modifications, equivalent processes, as well as numerous structures to which the present invention can be applicable will be readily apparent to those of skill in the art to which the present invention is directed upon review of the instant specification.

### EXAMPLE

Unless otherwise noted, chemical reagents and solvents were or can be obtained from Aldrich Chemical Co., Milwaukee, Wis.

### Example 1

A sample of structured phosphor tape was made by applying a pressure sensitive adhesive to a phosphor-loaded film layer. The phosphor-loaded film layer contained cerium-doped yttrium aluminate (YAG:Ce) phosphor in a UV-curable binder. The phosphor-loaded film was made from a paste prepared by hand mixing 13.63 grams of YAG:Ce phosphor (designated QMK58/F-U1 by Phosphor Technology, Ltd. of Stevenage, England) into 20.45 grams of UV-curable resin (designated NOA 65 by Norland Products, Cranbury, N.J.). The paste was coated onto a structured polymeric sheet having a cross-section as shown in FIG. 4 by hand using the 100 micrometer gap of a square multiple clearance applicator (designated PAR-05353 by BYK-Gardner USA, Columbia, Md. The wet film was cured by placing it below a bank of UV bulbs (designated F15T8/350BL by Osram Sylvania, Danvers,Mass.) for about 20 minutes. A pressure-sensitive adhesive (designated Optically Clear Adhesive (OCA) specifically a cross-linked iso-octyl acrylate/acetic acid (90/10) PSA) was coated onto the structured surface of the phosphor coating and covered with a protective release liner to produce a phosphor tape with the following layered construction: 1) phosphor-loaded film; 2) pressure-sensitive adhesive; 3) release liner. This construction can then be applied to an UV or blue LED to produce a white light LED.

What is claimed is:

1. A phosphor tape article, comprising:
a phosphor layer comprising a phosphor and a polymeric binder material, the phosphor layer having a structured surface; and
a pressure sensitive adhesive layer disposed adjacent the phosphor layer such that light transmitted through the pressure sensitive adhesive layer is received by the phosphor layer through the structured surface.

2. An article according to claim 1, wherein the pressure sensitive adhesive layer also has a structured surface.

3. An article according to claim 2, wherein the structured surface of the pressure sensitive adhesive layer is complimentary with the structured surface of the phosphor layer.

4. An article according to claim 1, further comprising a release layer disposed on the pressure sensitive adhesive layer, wherein the pressure sensitive adhesive layer is disposed between the phosphor layer and the release layer.

5. An article according to claim 1, further comprising a hardcoat layer disposed on the phosphor layer, wherein the phosphor layer is disposed between the pressure sensitive adhesive layer and the hardcoat layer.

6. An article according to claim 1, wherein the pressure sensitive adhesive layer is disposed on the phosphor layer.

7. An article according to claim 1, wherein the pressure sensitive adhesive layer comprises a pressure sensitive adhesive that builds adhesion over a time interval.

8. An article according to claim 1, wherein the pressure sensitive adhesive layer comprises a curing agent.

9. An article according to claim 1, wherein the pressure sensitive adhesive layer comprises a silicone polymer.

10. An article according to claim 1, wherein the phosphor layer structured surface comprises a plurality of linear prismatic projections having an aspect ratio in a range of 0.5 to 10.

11. An article according to claim 1, wherein the phosphor layer structured surface comprises a plurality of pyramidal or conical projections having an aspect ratio in a range of 0.5 to 10.

12. A light emitting device, comprising:
an encapsulated LED that includes an ultraviolet or blue LED die disposed within a transparent encapsulating material; and
a phosphor tape disposed on the transparent encapsulating material, wherein the phosphor tape comprises:
a phosphor layer comprising a phosphor and a polymeric binder material, the phosphor layer having a structured surface; and
a pressure sensitive adhesive layer disposed adjacent the phosphor layer such that light transmitted through the pressure sensitive adhesive layer is received by the phosphor layer through the structured surface.

13. A device according to claim 12, wherein the pressure sensitive layer also has a structured surface on at least one side thereof.

14. A device according to claim 12, wherein the pressure sensitive adhesive layer further comprises an ultraviolet or blue light curing agent.

15. A device according to claim 12, wherein the encapsulating material has a first index of refraction, the pressure sensitive adhesive layer has a second index of refraction, and the phosphor layer polymeric binder material has a third index of refraction, and the first, second and third index of refractions all have a value within 0.1 at a visible wavelength.

16. A device according to claim 12, wherein the encapsulating material has a first index of refraction, the pressure sensitive adhesive layer has a second index of refraction, and the phosphor layer polymeric binder material has a third index of refraction, and the second index of refraction has a value between the first and third index of refraction.

17. A device according to claim 12, wherein the structured surface comprises a plurality of prismatic projections directed toward the LED die.

18. A device according to claim 17, wherein the plurality of prismatic projections have an aspect ratio in a range of 0.5 to 10.

19. A device according to claim 12, wherein the structured surface comprises a plurality of pyramidal or conical projections directed toward the LED die.

20. A device according to claim 19, wherein the plurality of pyramidal or conical projections have an aspect ratio in a range of 0.5 to 10.
